(19) United States
(12) Patent Application Publication
(10) Pub. No.: US 2026/0156809 A1
(43) Pub. Date: Jun. 4, 2026

(54) SEMICONDUCTOR DEVICE AND METHOD FOR FABRICATING THEREOF

(71) Applicant: NANYA TECHNOLOGY CORPORATION, New Taipei City (TW)

(72) Inventor: Chung-Lin HUANG, New Taipei City (TW)

(21) Appl. No.: 18/966,145

(22) Filed: Dec. 3, 2024

(51) Int. Cl. H10B 12/00

(52) U.S. Cl. CPC H10B 12/488; H10B 12/05

(57) ABSTRACT

A method of fabricating a semiconductor device that includes forming a dummy channel structure, forming a gate electrode surrounding the dummy channel structure, forming a word line surrounding the gate electrode, removing the dummy channel structure to form an opening, forming a gate dielectric in the opening, and forming a channel structure in the opening.

### BACKGROUND

Dynamic random-access memory (dynamic RAM or DRAM) is a type of random-access semiconductor memory that stores each bit of data in a memory cell. DRAM is known for its high speed operation, high density, and scalability. However, as the production of DRAM scales up, the manufacturing of DRAM becomes more challenging and more prone to defects. For example, the gate electrode may not effectively control the channel structure. Therefore, there is a need for a credible apparatus and fabrication method for a semiconductor device.

### SUMMARY

The disclosure provides a method of fabricating a semiconductor device that includes forming a dummy channel structure, forming a gate electrode surrounding the dummy channel structure, forming a word line surrounding the gate electrode, removing the dummy channel structure to form an opening, forming a gate dielectric in the opening, and forming a channel structure in the opening.

In some embodiments, the dummy channel structure is formed overlapping a capacitor.

In some embodiments, the method further includes forming a dielectric layer on the capacitor, in which the dummy channel structure is formed on the dielectric layer.

In some embodiments, the opening exposes the capacitor.

In some embodiments, the gate dielectric is formed extending vertically from the capacitor and along a sidewall of the opening.

In some embodiments, the method further includes etching back the gate electrode such that a top surface of the gate electrode is lower than a top surface of the dummy channel structure.

In some embodiments, the word line is formed with a top surface lower than a top surface of the gate electrode.

In some embodiments, forming the word line includes forming a word line material surrounding the dummy channel structure, forming a hard mask structure over the word line material, and etching the word line material through the hard mask structure to form the word line.

In some embodiments, the hard mask structure is formed overlapping the dummy channel structure.

In some embodiments, the method further includes forming a spacer along a sidewall of the hard mask structure before etching the word line material.

The disclosure provides a semiconductor device that includes a capacitor, a channel structure extending vertically from a top surface of the capacitor, a gate dielectric surrounding the channel structure, a gate electrode surrounding the gate dielectric, and a word line surrounding the gate electrode.

In some embodiments, the gate dielectric has a linear cross-sectional profile.

In some embodiments, the gate dielectric extends vertically from a top surface of the capacitor.

In some embodiments, a bottom surface of the gate dielectric is lower than a bottom surface of the gate electrode.

In some embodiments, a top surface of the gate dielectric is higher than a top surface of the gate electrode.

In some embodiments, the device further includes a dielectric layer in contact with a sidewall of the gate dielectric.

In some embodiments, the channel structure is made with an oxide semiconductor material.

In some embodiments, the channel structure is made with indium gallium zinc oxide (IGZO).

In some embodiments, the gate electrode has a ring-shape top profile.

In some embodiments, the word line has a bar-shape top profile.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic view of a memory array, in accordance with some embodiments of the present disclosure.

FIG. 2 is a schematic view of a memory cell, in accordance with some embodiments of the present disclosure.

FIG. 3 is a flow chart of a method of fabricating a semiconductor device, in accordance with some embodiments of the present disclosure.

FIGS. 4A to 21B illustrate a method of fabricating a semiconductor device, in accordance with some embodiments of the present disclosure.

FIGS. 22A to 23B illustrate a method of fabricating a semiconductor device, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

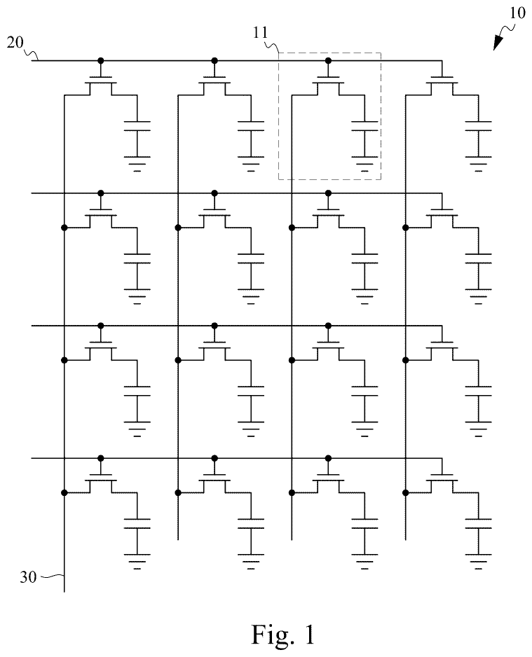

FIG. 1 is a schematic view of a memory array, in accordance with some embodiments of the present disclosure. In some embodiments, the memory array 10 includes multiple memory cells 11 laid out in a rectangular matrix. FIG. 1 shows a simple example with a four-by-four cell matrix. Other memory matrices many be thousands of cells in height and width. In some embodiments, the memory array 10 can be a dynamic random-access memory (dynamic RAM or DRAM).

Each row of memory cells 11 is connected by a word line 20 and each column of memory cells 11 is connected by a bit line 30. A plurality of word lines 20 may extend horizontally. The word lines 20 are parallel to each other. Additionally, the word lines 20 may be spaced apart from each other at substantially equal intervals. On the other side, a plurality of bit lines 30 may extend vertically. Similar to the word lines 20, the bit lines 30 are parallel to each other and may be spaced apart from each other at substantially equal intervals.

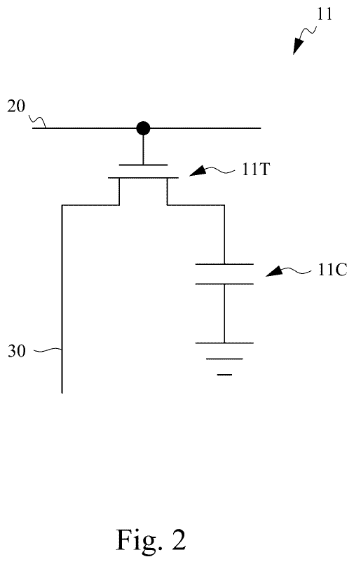

FIG. 2 is a schematic view of a memory cell, in accordance with some embodiments of the present disclosure. Specifically, FIG. 2 is a close-up view of FIG. 1. In some embodiments, a memory cell 11 includes an access transistor 11T and a storage capacitor 11C electrically connected to the access transistor 11T.

In some embodiments, the access transistor 11T is an NMOS transistor, and is configured to control the channel to the memory cell 11 by opening or closing the gate of the access transistor 11T. In some embodiments, the storage capacitor 11C is configured to store information according to the state of electrical charges stored therein. The storage capacitor 11C in an empty state, that is, no charge, is denoted a logic value of 0. The storage capacitor 11C in a fully-charged state is denoted a logic value of 1. The memory cell 11 stores a bit of data by means of the two extreme states of charges stored in the storage capacitor 11C.

In some embodiments, a word line 20 connected to the access transistor 11T is used to control the gate of the access transistor 11T by applying a voltage to the gate of the access transistor 11T. In some embodiments, a bit line 30 is arranged perpendicular to the word line 20 and is also connected to the access transistor 11T. When the gate of the access transistor 11T is turned on, the access transistor 11T connects the storage capacitor 11C to the bit line 30 such that the logic value stored in the storage capacitor 11C will be read on the bit line 30.

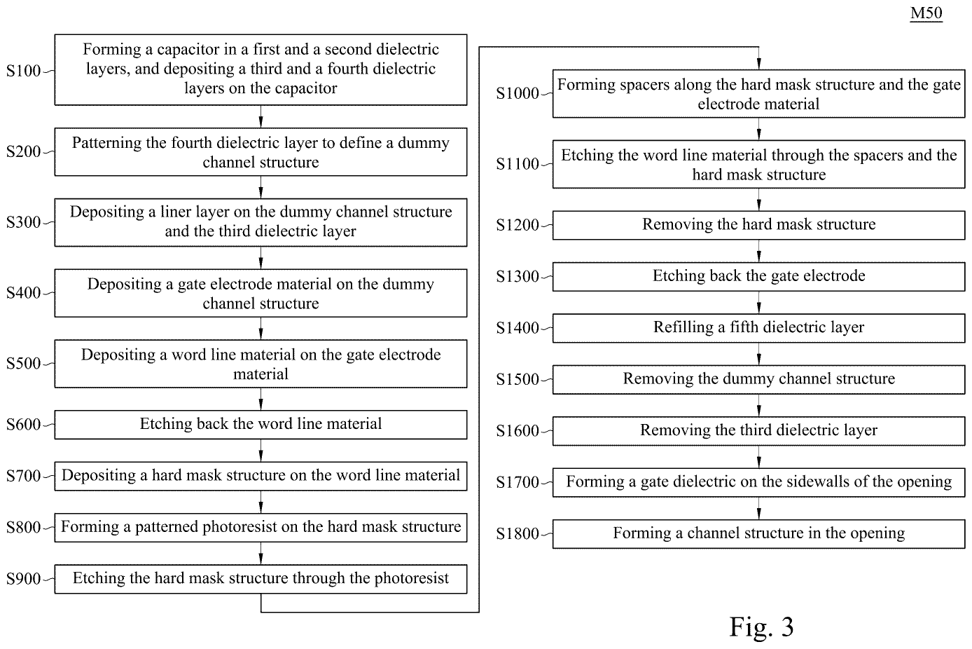

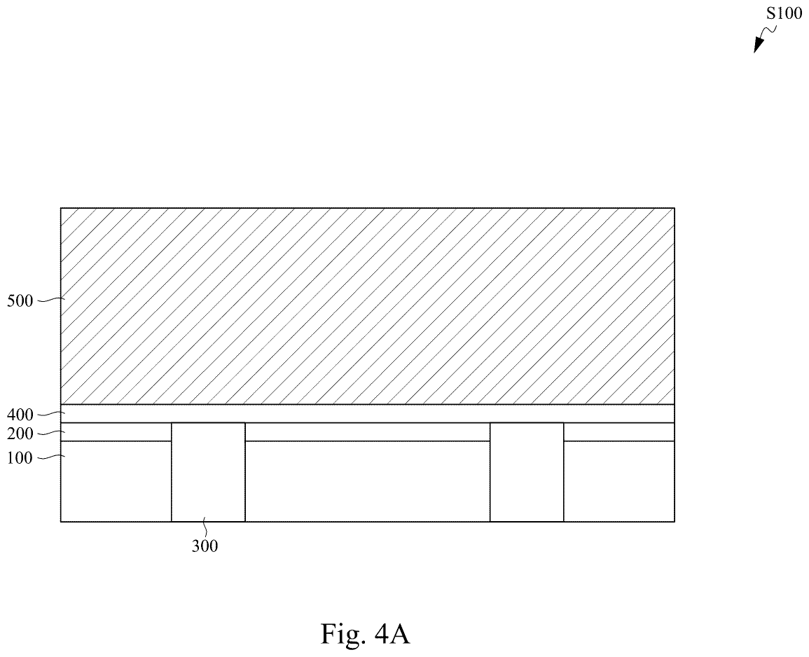

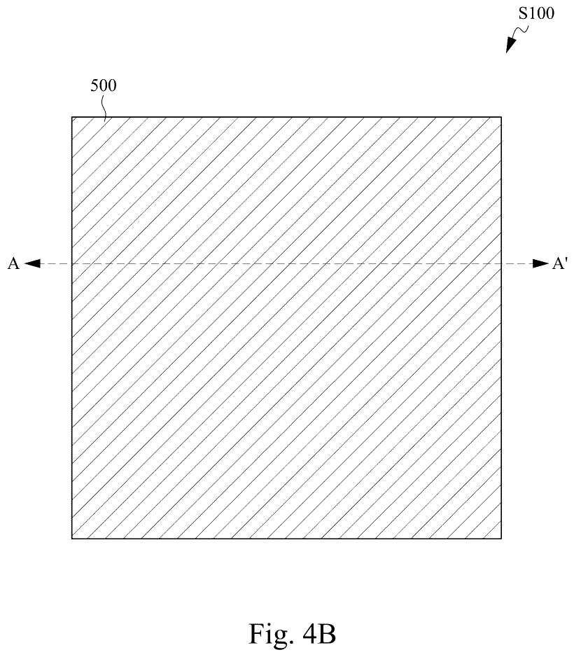

FIG. 3 is a flow chart of a method of fabricating a semiconductor device, in accordance with some embodiments of the present disclosure. FIGS. 4A to 21B illustrate a method of fabricating a semiconductor device, in accordance with some embodiments of the present disclosure. Specifically, FIGS. 4A to 21A are cross-sectional views alone line A-A′ of the top views of FIGS. 4B to 21B, respectively.

The semiconductor device and the fabricating method M50 will be discussed in conjunction with reference to FIGS. 4A to 21B. As illustrated in FIG. 3, a fabricating method M50 may include the following operations S100, S200, S300, S400, S500, S600, S700, S800, S900, S1000, S1100, S1200, S1300, S1400, S1500, S1600, S1700, and S1800.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

The method M50 starts from operation S100 by forming a capacitor in a first and a second dielectric layers, and depositing a third and a fourth dielectric layers on the capacitor. Referring to FIG. 4A and FIG. 4B, the first dielectric layer 100 and the second dielectric layer 200 are deposited sequentially on a substrate (not shown), a plurality of capacitors 300 are formed in the first dielectric layer 100 and the second dielectric layer 200, and the third dielectric layer 400 and fourth dielectric layer 500 are deposited sequentially on the second dielectric layer 200 and covering the capacitors 300.

In some embodiments, the first dielectric layer 100 is deposited on a substrate (not shown). In some embodiments, the first dielectric layer 100 is configured to provide an electrical isolation between the capacitors 300 that will be formed in the subsequent steps. The first dielectric layer 100 is made with a dielectric material. In some embodiments, the first dielectric layer 100 is made with silicon dioxide (SiO₂).

The first dielectric layer 100 may be deposited by using chemical vapor deposition (CVD), plasma-enhanced chemical vapor deposition (PECVD), atomic layer deposition (ALD), physical vapor deposition (PVD), low-pressure chemical vapor deposition (LPCVD), flowable chemical vapor deposition (FCVD), or other suitable deposition processes.

In some embodiments, the second dielectric layer 200 is deposited on the first dielectric layer 100. In some embodiments, the second dielectric layer 200 is configured to provide an electrical isolation between the capacitors 300 that will be formed in the subsequent steps. The second dielectric layer 200 is made with a dielectric material. In some embodiments, the first dielectric layer 100 and the second dielectric layer 200 are made with different dielectric materials. In some embodiments, the second dielectric layer 200 is made with silicon nitride (SiN).

The second dielectric layer 200 may be deposited by using CVD, PECVD, ALD, PVD, LPCVD, FCVD or other suitable deposition processes. In some embodiments, the vertical thickness of the second dielectric layer 200 may be less than the vertical thickness of the first dielectric layer 100.

In some embodiments, the first dielectric layer 100 and the second dielectric layer 200 may be patterned to form openings. A mask pattern (not shown) may be formed on the second dielectric layer 200. Subsequently, the first dielectric layer 100 and the second dielectric layer 200 are etched through the mask pattern to form openings. In some embodiments, after etching, sets of the first dielectric layer 100 and the second dielectric layer 200 may be separated from each other by the openings, in which each opening may extend vertically from the underlying structure in the substrate (not shown) and is parallel to each other. In some embodiments, the openings may be regularly arranged at substantially equal intervals from each other horizontally.

Next, the capacitor 300 can be formed into the openings. In other words, a capacitor 300 replaces each opening. In some embodiments, the capacitors 300 are parallel to each other and may be regularly arranged at substantially equal intervals from each other.

The capacitor 300 may include a bottom electrode, a capacitor dielectric layer over the bottom electrode, and a top electrode over the capacitor dielectric layer. In some embodiments, the bottom electrode and the top electrode of the capacitor 300 may include conductive material. In some embodiments, the bottom electrode and the top electrode may include metal. In some embodiments, the bottom electrode and the top electrode may include titanium nitride (TiN). In some embodiments, the capacitor dielectric layer of the capacitor 300 may include dielectric material. Each of the bottom electrode, capacitor dielectric layer, and top electrode of the capacitor 300 may be deposited by using CVD, PECVD, ALD, PVD, LPCVD, FCVD or other suitable deposition processes, sequentially.

A planarization process may be performed to the capacitor 300, so as to level the capacitor 300 with the second dielectric layer 200. The leveled capacitor 300 is coplanar to the second dielectric layer 200, therefore share the same top surface. That is, the top surface the leveled capacitor 300 and the top surface of the second dielectric layer 200 may be coterminous with each other. A chemical mechanical polishing (CMP) process can be used for the planarization process. The CMP process may stop when the second dielectric layer 200 is exposed.

Next, the third dielectric layer 400 may be deposited on the capacitor 300 and the second dielectric layer 200. In some embodiments, the third dielectric layer 400 covers the capacitor 300. The third dielectric layer 400 is configured to provide an electrical isolation between some conductive structures (e.g. word line) that will be formed in the subsequent steps. In some embodiments, a part of the third dielectric layer 400 also acts as a sacrificial structure for some conductive structures (e.g. channel) that will be formed in the subsequent steps.

The third dielectric layer 400 is made with a dielectric material. In some embodiments, the third dielectric layer 400 and the first dielectric layer 100 are made with the same material. In some embodiments, the third dielectric layer 400 is made with silicon dioxide (SiO₂). The third dielectric layer 400 may be deposited by using CVD, PECVD, ALD, PVD, LPCVD, FCVD, or other suitable deposition processes.

In some embodiments, the fourth dielectric layer 500 is deposited on the third dielectric layer 400. The fourth dielectric layer 500 is made with a dielectric material. In some embodiments, the fourth dielectric layer 500 and the second dielectric layer 200 are made with the same material. In some embodiments, the fourth dielectric layer 500 is made with silicon nitride (SiN). The fourth dielectric layer 500 may be deposited by using CVD, PECVD, ALD, PVD, LPCVD, FCVD or other suitable deposition processes. In some embodiments, the vertical thickness of the fourth dielectric layer 500 may be greater than the vertical thickness of the third dielectric layer 400.

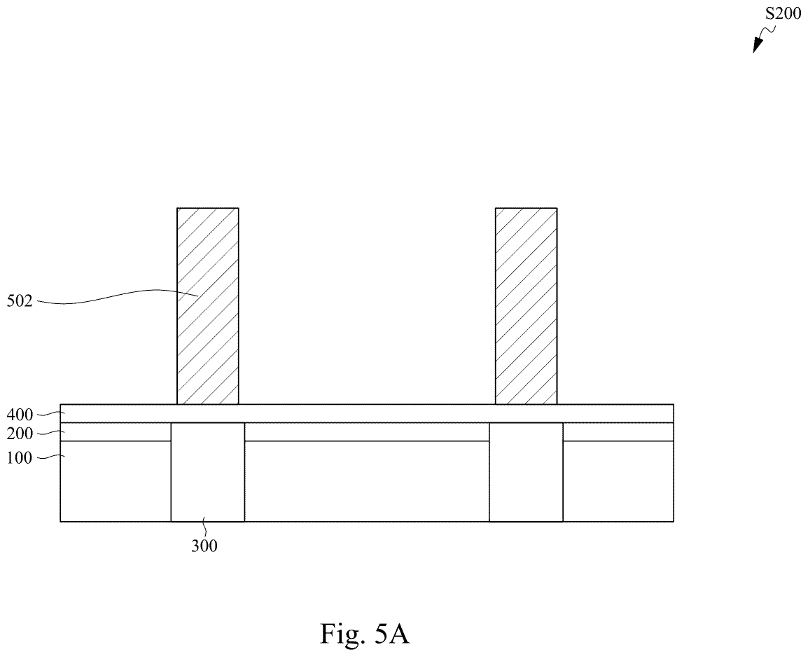

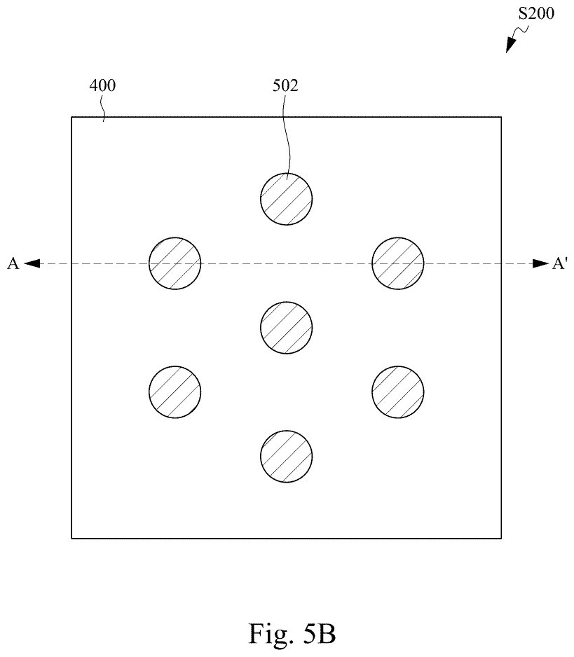

The method M50 proceeds to operation S200 by patterning the fourth dielectric layer to define a dummy channel structure. Referring to FIG. 5A and FIG. 5B, the fourth dielectric layer 500 may be patterned to define the dummy channel structures 502. A mask pattern (not shown) may be formed on the fourth dielectric layer 500. Subsequently, the fourth dielectric layer 500 is etched through the mask pattern.

In some embodiments, operation S200 may include photolithography. In some embodiments, the mask pattern is formed on the fourth dielectric layer 500 right on top of the capacitor 300. Thus, portions of the fourth dielectric layer 500 overlapping with the capacitors 300 may not be etched during the etching process and the dummy channel structures 502 are defined after the etching process.

In some embodiments, each of the dummy channel structures 502 may overlap with a corresponding capacitor 300. In some embodiments, the dummy channel structure 502 is configured to act as a placeholder for the channel structure that will be formed in the subsequent steps.

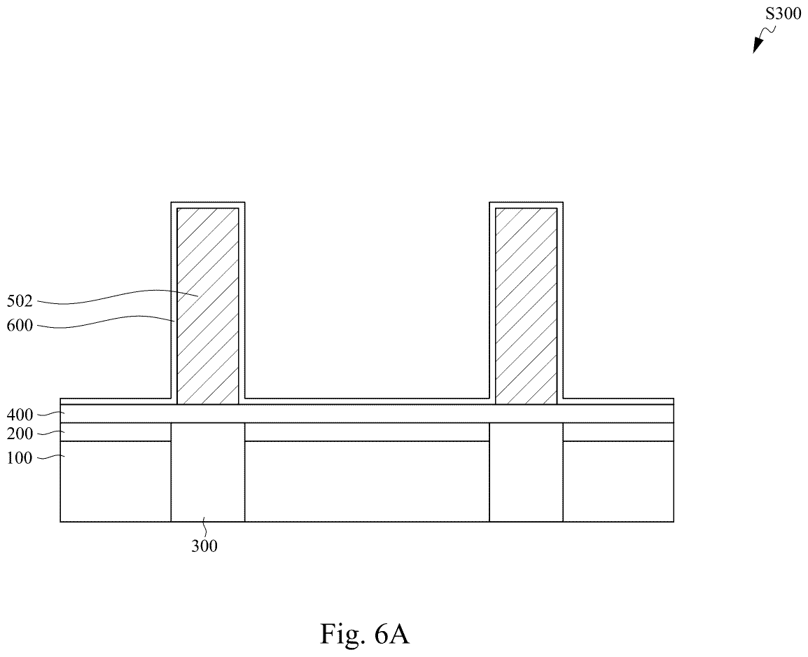

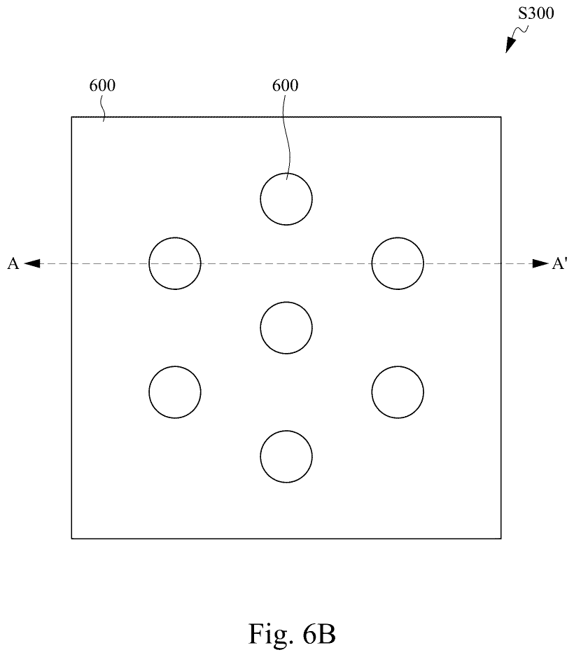

The method M50 proceeds to operation S300 by depositing a liner layer on the dummy channel structure and the third dielectric layer. Referring to FIG. 6A and FIG. 6B, a liner layer 600 is deposited on the dummy channel structure 502 and the third dielectric layer 400.

In some embodiments, the liner layer 600 extends from the top surface of the third dielectric layer 400 to the dummy channel structure 502 and covers the top and sidewalls of the dummy channel structure 502.

The liner layer 600 may be made with a dielectric material. In some embodiments, the liner layer 600 is made with the same material as the third dielectric layer 400 or the first dielectric layer 100. In some embodiments, the liner layer 600 is made with silicon dioxide (SiO₂). The liner layer 600 may be deposited by using CVD, PECVD, ALD, PVD, LPCVD, FCVD, or other suitable deposition processes.

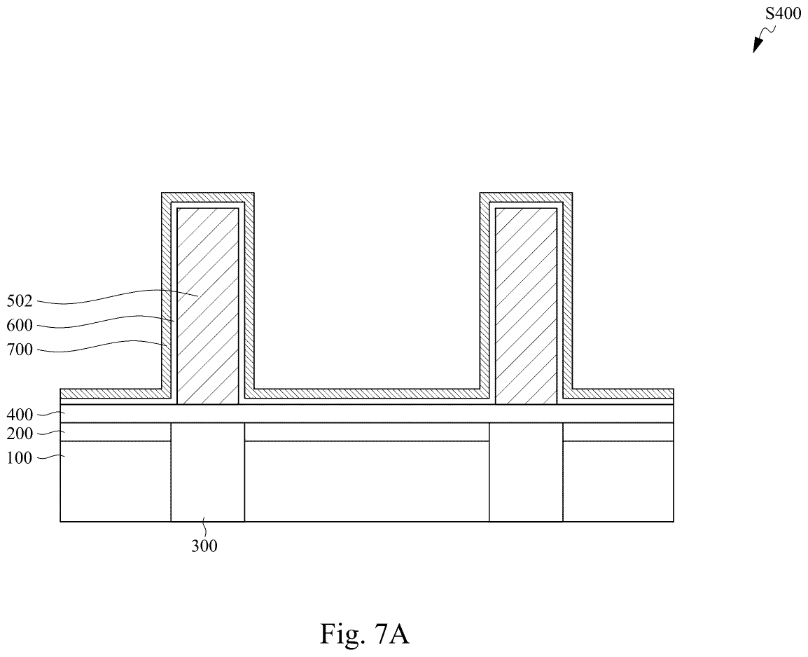

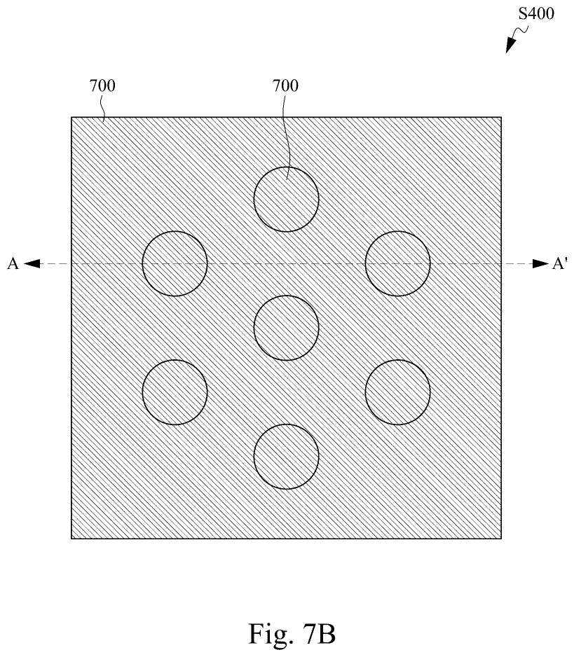

The method M50 proceeds to operation S400 by depositing a gate electrode material on the liner layer. Referring to FIG. 7A and FIG. 7B, a gate electrode material 700 is deposited on the liner layer 600. In some embodiments, the gate electrode material 700 extends from the top surface of the liner layer 600 and covers the liner layer 600.

The gate electrode material 700 may be made with a conductive material. In some embodiments, the gate electrode material 700 may include metal. In some embodiments, the gate electrode material 700 may include titanium nitride (TiN). The gate electrode material 700 may be deposited by using CVD, PECVD, ALD, PVD, LPCVD, FCVD, or other suitable deposition processes.

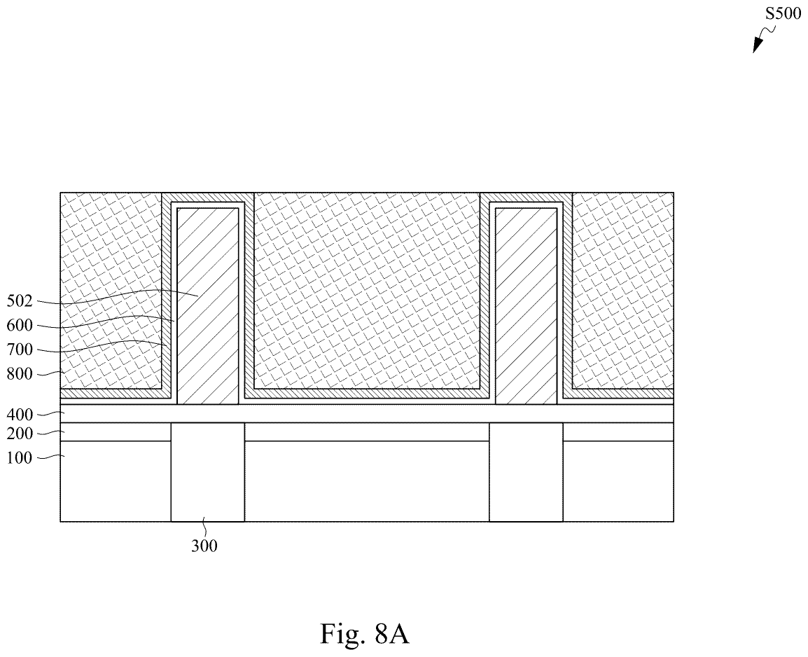

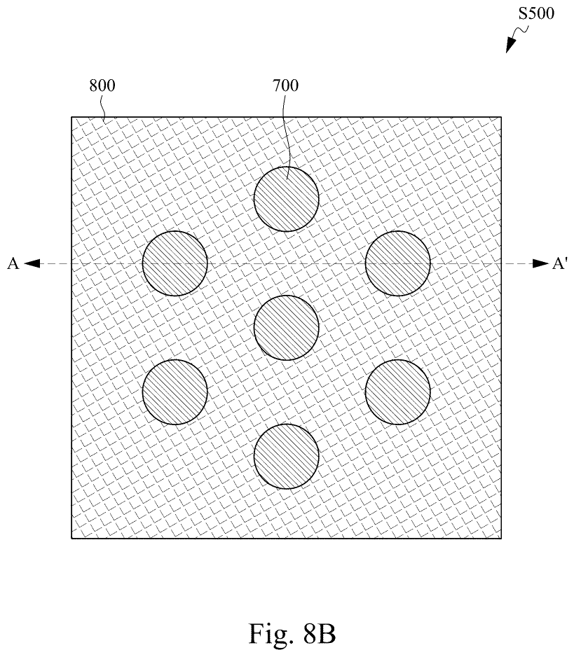

The method M50 proceeds to operation S500 by depositing a word line material on the gate electrode material. Referring to FIG. 8A and FIG. 8B, a word line material 800 is deposited on the gate electrode material 700.

The word line material 800 may be made with a conductive material. In some embodiments, the word line material 800 may include metal. In some embodiments, the word line material 800 may include Tungsten (W). The word line material 800 may be deposited by using CVD, PECVD, ALD, PVD, LPCVD, FCVD, or other suitable deposition processes.

In some embodiments, a planarization process may be performed to the word line material 800, so as to expose the top surface of the gate electrode material 700. The leveled word line material 800 is coplanar to the gate electrode material 700, therefore share the same top surface. That is, the top surface the word line material 800 and the top surface of the gate electrode material 700 may be coterminous with each other. A chemical mechanical polishing (CMP) process can be used for the planarization process.

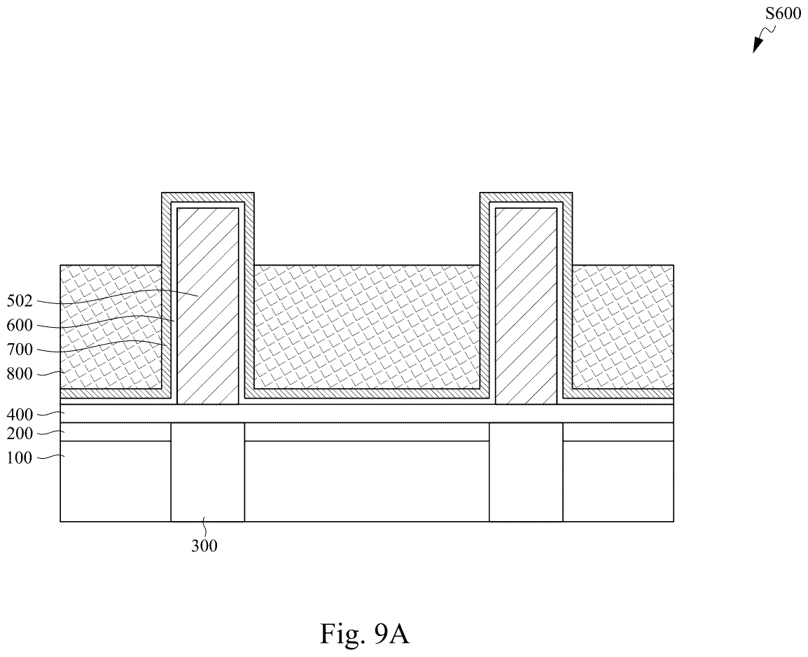

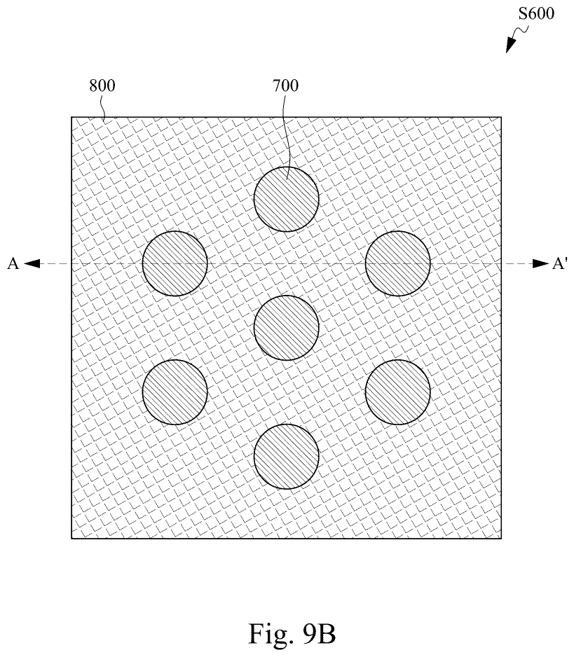

The method M50 proceeds to operation S600 by etching back the word line material. Referring to FIG. 9A and FIG. 9B, the word line material 800 is etched back to lower the top surface of the word line material 800. As a result, portions of the gate electrode material 700 and the dummy channel structure 502 may protrude from the top surface of the etched word line material 800.

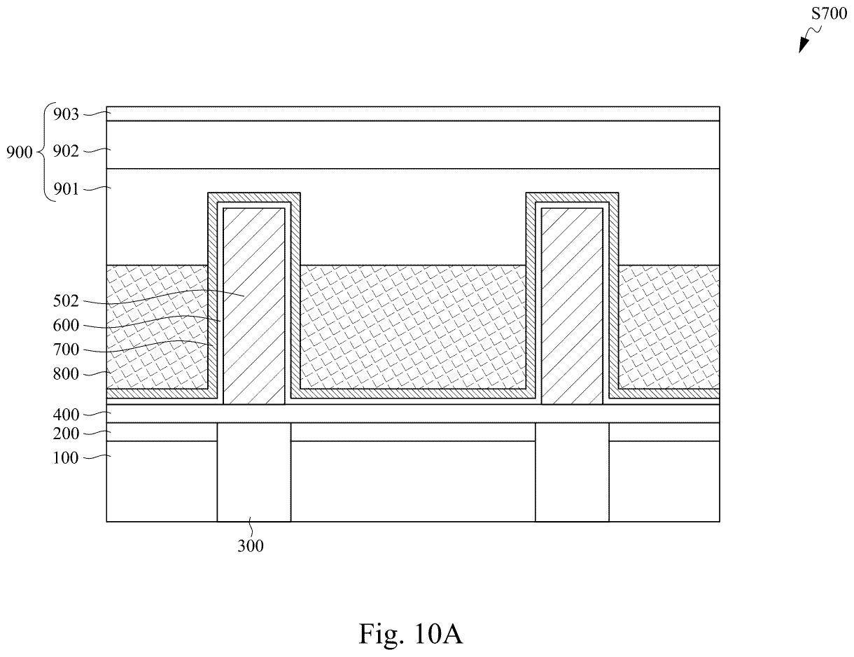

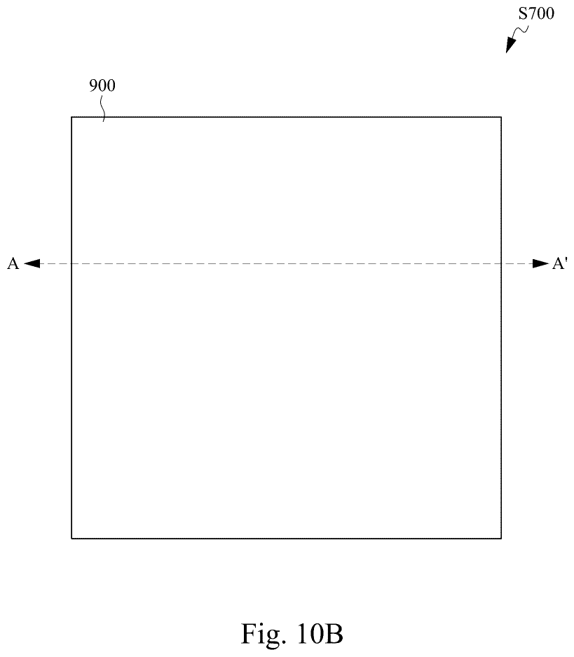

The method M50 proceeds to operation S700 by depositing a hard mask structure on the word line material. Referring to FIG. 10A and FIG. 10B, a hard mask structure 900 is deposited on the word line material 800 and the exposed portion of the gate electrode material 700.

In some embodiments, the hard mask structure 900 may include the first hard mask layer 901, the second hard mask layer 902, and the third hard mask layer 903. The first hard mask layer 901, the second hard mask layer 902, and the third hard mask layer 903 may be deposited by using CVD, PECVD, ALD, PVD, LPCVD, FCVD, or other suitable deposition processes, sequentially.

In some embodiments, the first hard mask layer 901 is deposited on the word line material 800 and covers the exposed portion of the gate electrode material 700. In some embodiments, the first hard mask layer 901 may be an under layer film.

In some embodiments, the second hard mask layer 902 is deposited on the first hard mask layer 901. In some embodiments, the second hard mask layer 902 is made with a dielectric material. In some embodiments, the second hard mask layer 902 may include carbon. In some embodiments, the second hard mask layer 902 may include amorphous carbon (a-carbon).

In some embodiments, the third hard mask layer 903 is deposited on the second hard mask layer 902. In some embodiments, the third hard mask layer 903 may be a dielectric anti-reflection coating (DARC) layer. In some embodiments, the third hard mask layer 903 may include silicon. In some embodiments, the third hard mask layer 903 may be a silicon oxy-nitride (SiOₓN_{y}) or any suitable antireflective material layer. In some embodiments, the third hard mask layer 903 is configured to reduce reflectivity during photoresist patterning. Additionally, an organic antireflective coating (not shown) layer may be used optionally over the third hard mask layer 903 for photoresist performance enhancement.

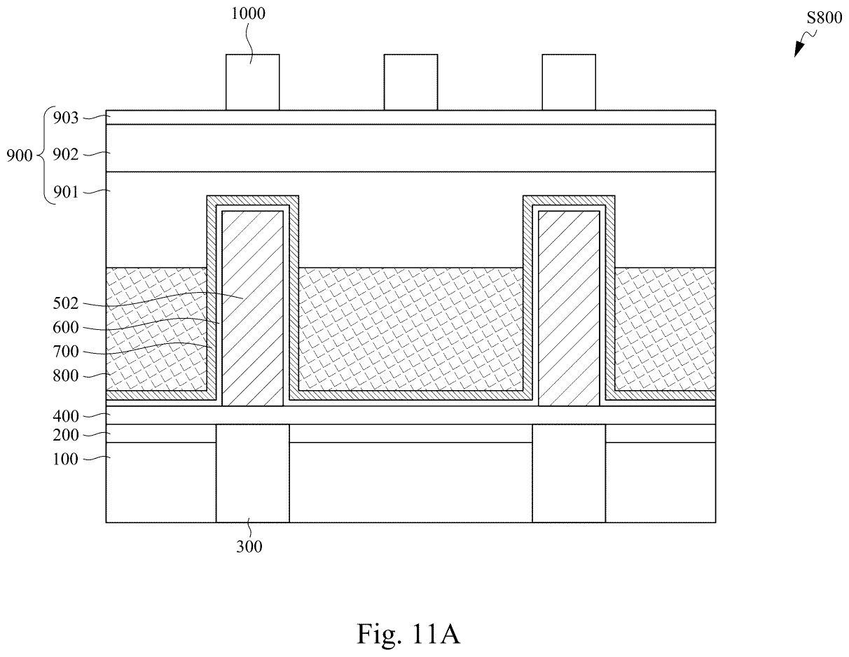

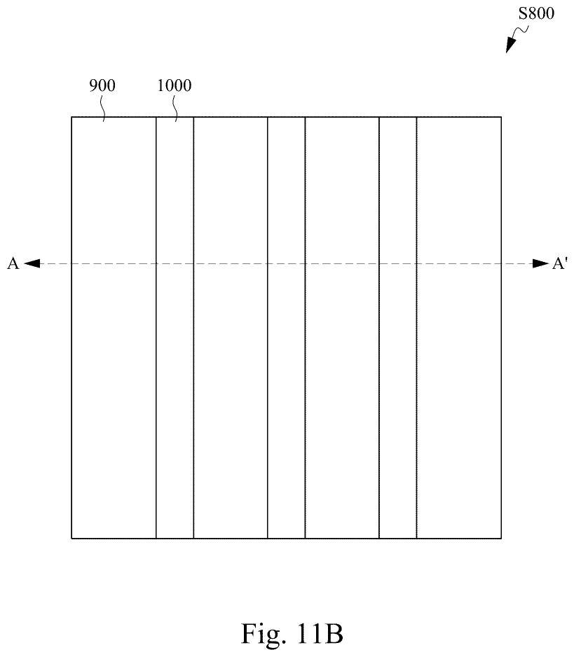

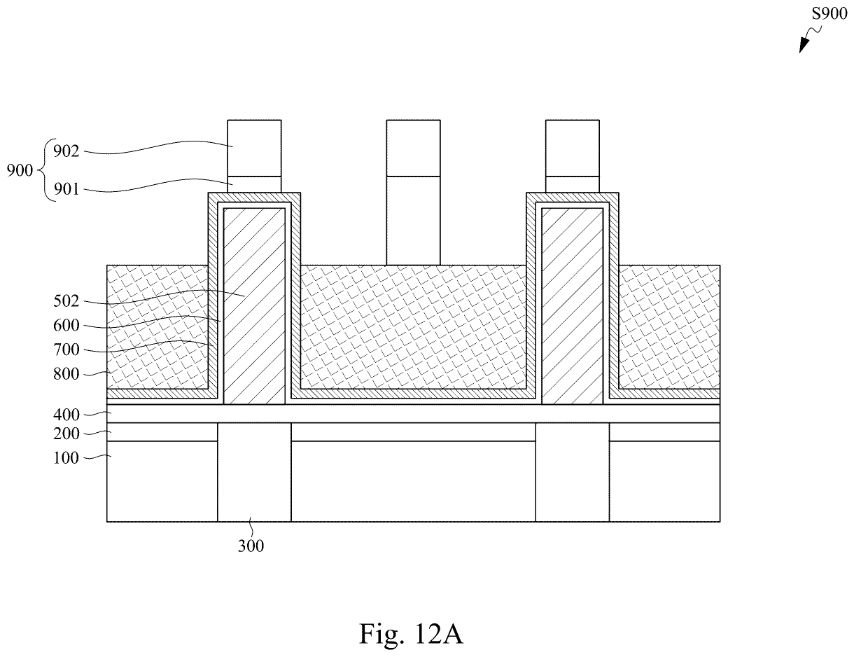

The method M50 proceeds to operation S800 by forming a patterned photoresist on the hard mask structure. Referring to FIG. 11A and FIG. 11B, a patterned photoresist 1000 is formed on the hard mask structure 900. A photoresist material layer (not shown) can be formed on the hard mask structure 900 using suitable deposition processes, such as spin coating. Then the photoresist material layer is exposed to a light source through a photomask (not shown) that has a specific pattern. In some embodiments, the area of the photoresist material layer becomes soluble when exposed to light. As a result, the exposed area of the photoresist material layer can be washed away to define the patterned photoresists 1000.

In some embodiments, the patterned photoresist 1000 may be on top of the hard mask structure 900 over the dummy channel structure 502. The patterned photoresist 1000 is configured to act as an etch protector for the underneath hard mask structure 900 over the dummy channel structure 502 in the subsequent etching process.

In some embodiments, the patterned photoresist 1000 may also be on top of the hard mask structure 900 over the word line material 800. The patterned photoresist 1000 is also configured to act as an etch protector for the underneath hard mask structure 900 over the word line material 800 in the subsequent etching process.

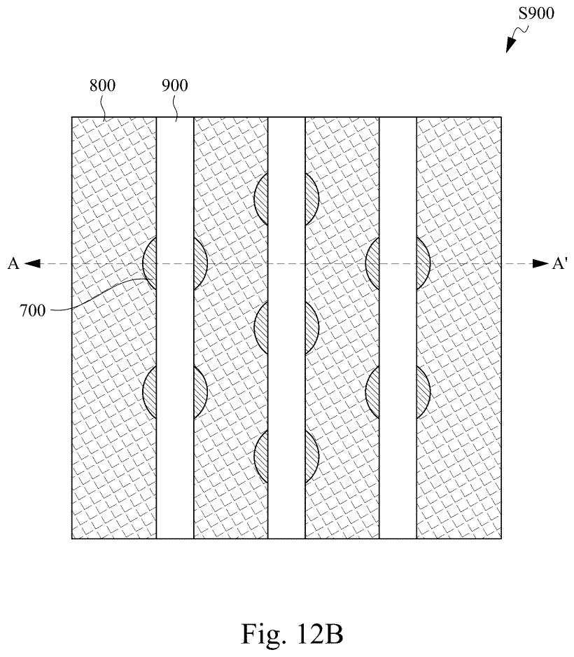

The method M50 proceeds to operation S900 by etching the hard mask structure through the photoresist. Referring to FIG. 12A and FIG. 12B, the hard mask structure 900 is etched through the photoresist 1000. In some embodiments, the hard mask structures 900 over the dummy channel structure 502 and over the word line material 800 are protected from the etching process through the photoresist 1000.

In some embodiments, the etching process is configured to etch the hard mask structure 900 and may leave other exposed materials (e.g. the gate electrode material 700 and word line material 800) with little or no etching. In some embodiments, the etching process may include certain etchants, such as carbon tetrafluoride (CF₄), sulfur dioxide (SO₂), or oxygen (O₂), that etch the hard mask structure 900.

In some embodiments, the photoresist 1000 may be removed after the etching process. In some embodiments, the removal of the photoresist 1000 includes a liquid resist stripper (not shown) that chemically alters the photoresist 1000 so that the photoresist 1000 no longer adheres to the hard mask structure 900.

In some embodiments, the removal of the photoresist 1000 exposes the third hard mask layer 903. In some embodiments, the third hard mask layer 903 may be removed during or after the removal of the photoresist 1000, and the second hard mask layer 902 is exposed. In some embodiments, the remaining hard mask structure 900 includes the first hard mask layer 901 and the second hard mask layer 902.

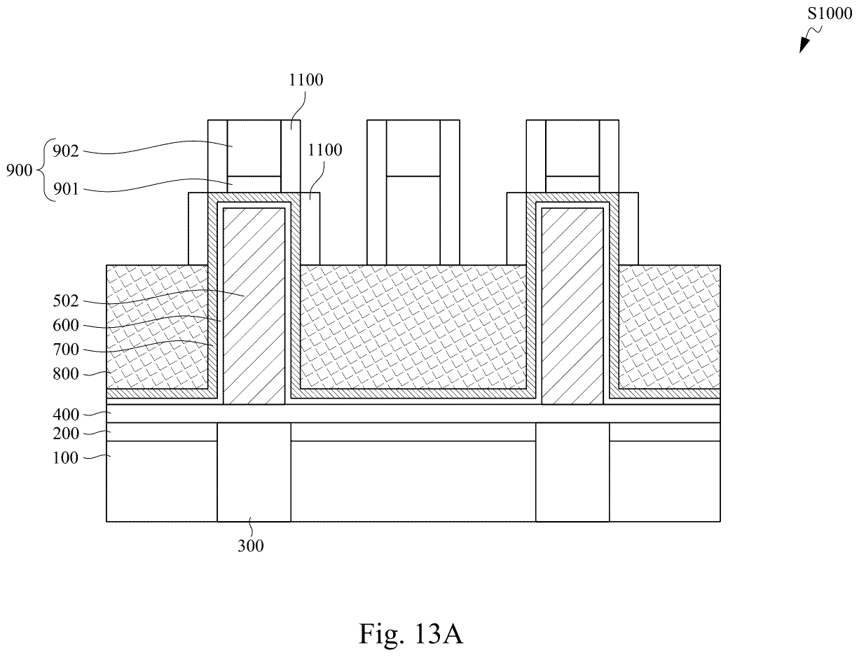

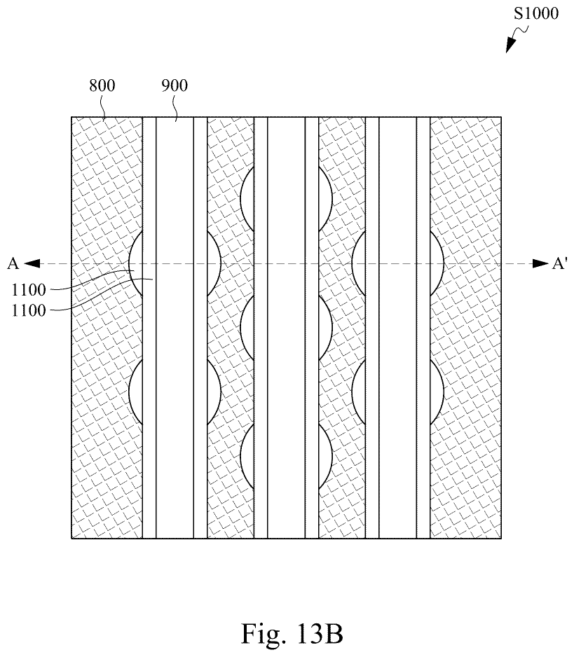

The method M50 proceeds to operation S1000 by forming spacers along the hard mask structure and the gate electrode material. Referring to FIG. 13A and FIG. 13B, a plurality of spacers 1100 are formed along the sidewalls of the hard mask structure 900 and the sidewalls of the gate electrode material 700.

In some embodiments, the spacer 1100 is made with a dielectric material. In some embodiments, the spacer 1100 is made with the same material as the liner layer 600, the third dielectric layer 400, or the first dielectric layer 100. In some embodiments, the spacer 1100 is made with silicon dioxide (SiO₂).

In some embodiments, a spacer blanket (not shown) may be formed over the underlying structure (e.g., the hard mask structure 900, the gate electrode material 700, and the word line material 800). The spacer blanket may be deposited by using CVD, PECVD, ALD, PVD, LPCVD, FCVD, or other suitable deposition processes. Then, an anisotropic etching process is performed on the spacer blanket to remove the horizontal portions of the spacer blanket, leaving only the vertical portions of the spacer blanket. The remaining vertical portions are referred to as the spacers 1100.

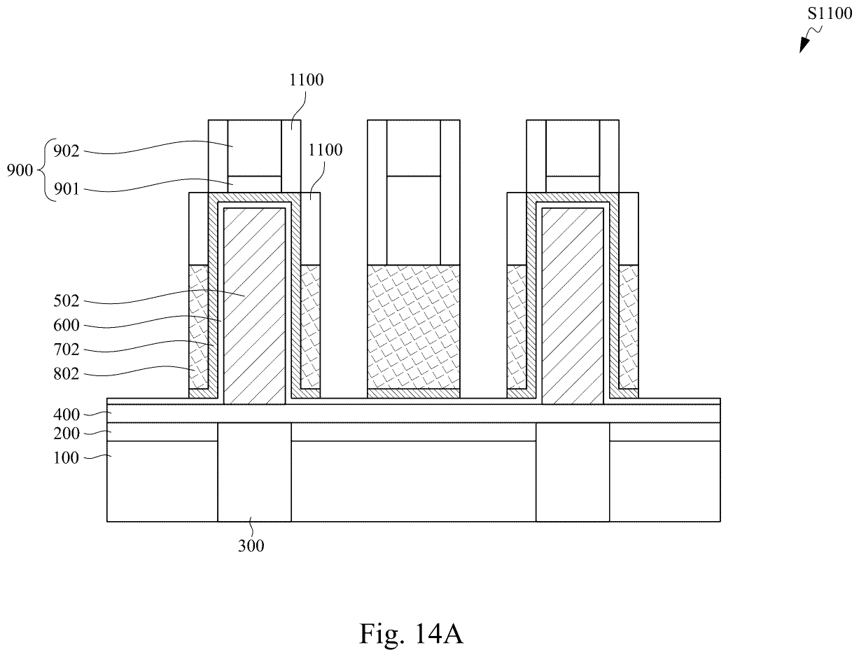

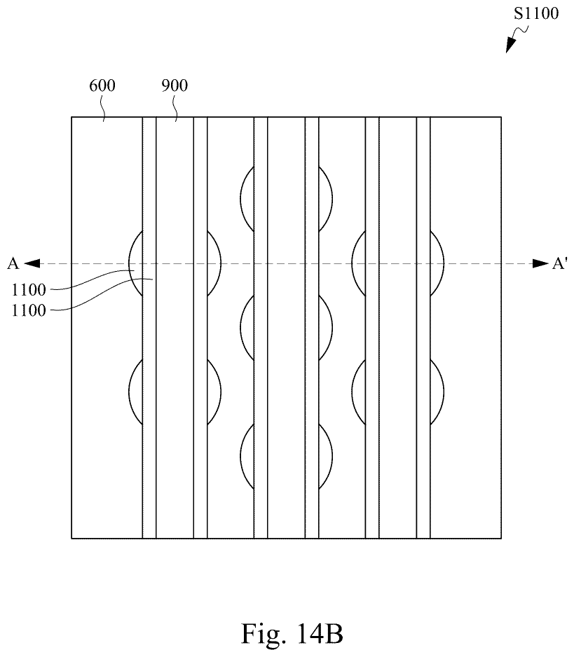

The method M50 proceeds to operation S1100 by etching the word line material through the spacers and the hard mask structure. Referring to FIG. 14A and FIG. 14B, the word line material 800 is etched, by using the spacers 1100 and the hard mask structure 900 as an etch mask, to form a plurality of word lines 802. In some embodiments, the word line 802 has a bar-shape top profile.

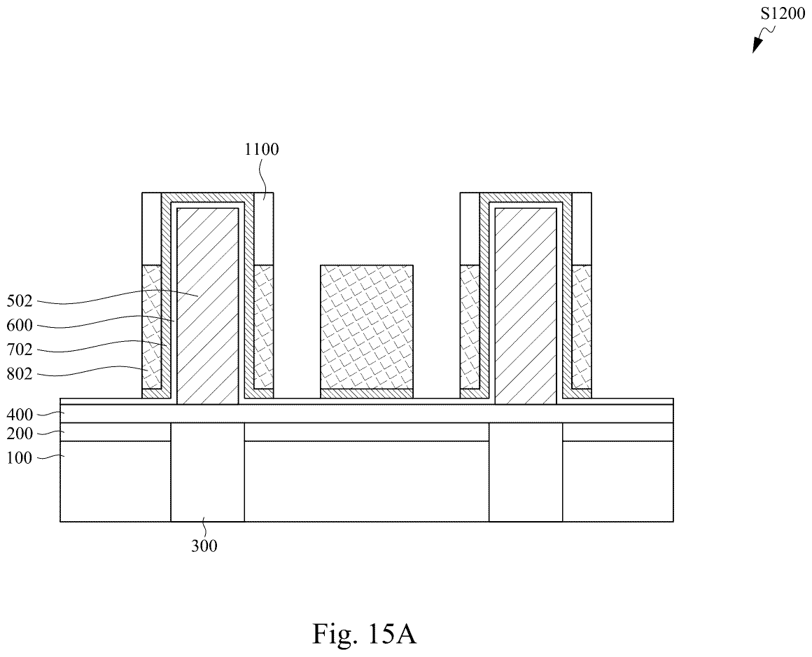

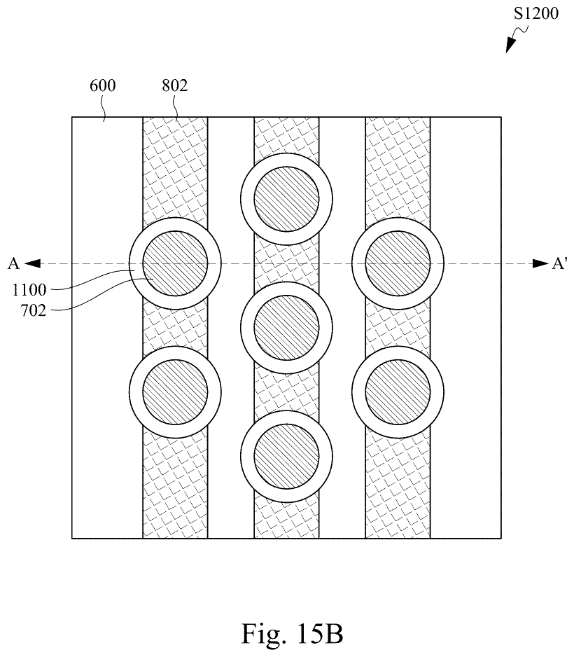

The method M50 proceeds to operation S1200 by removing the hard mask structure. Referring to FIG. 15A and FIG. 15B, the hard mask structures 900 are removed along with the spacers 1100 along the sidewalls of the hard mask structures 900. In some embodiments, the hard mask structures 900 can be removed using suitable etching processes. As a result, portions of the word lines 802 may be exposed. As shown in the top view of FIG. 15B, each of the word lines 802 may extend along a first direction, and may connect the gate electrodes 702 of the same column along the first direction. The word lines 802 are arranged along a second direction perpendicular to the first direction, and may be parallel to each other.

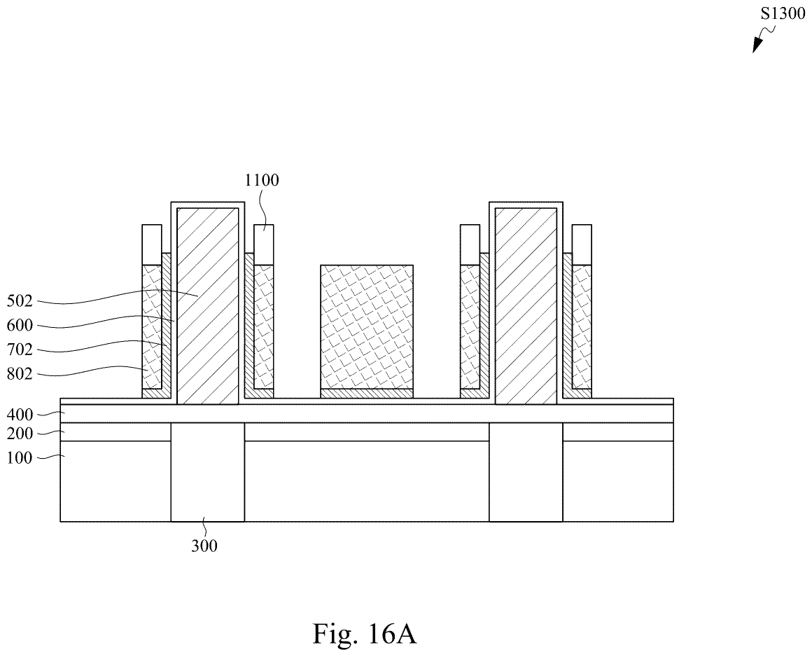

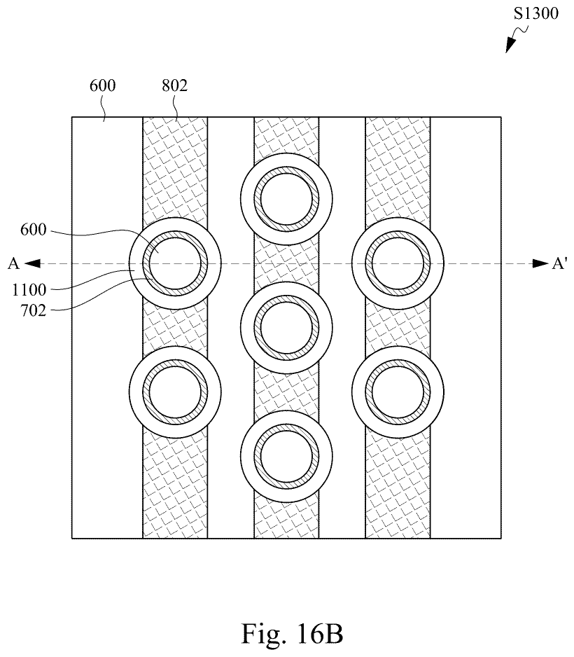

The method M50 proceeds to operation S1300 by etching back the gate electrode. Referring to FIG. 16A and FIG. 16B, a portion of the gate electrode 702 is etched back. Specifically, the top horizontal portion and the upper vertical portions of the gate electrode 702 are etched back.

In some embodiments, the etching process of S1300 is configured to etch the material of the gate electrode 702 until the liner layer 600 is exposed. In some embodiments, the etching process of S1300 may remove a small portion of the spacer 1100 as well.

In some embodiments, after the etching process of S1300, the gate electrode 702 has a ring-shape top profile. In some embodiments, the top surface of the gate electrode 702 is at a higher level than the top surface of the word line 802 and lower than the top surface of the dummy channel structure 502.

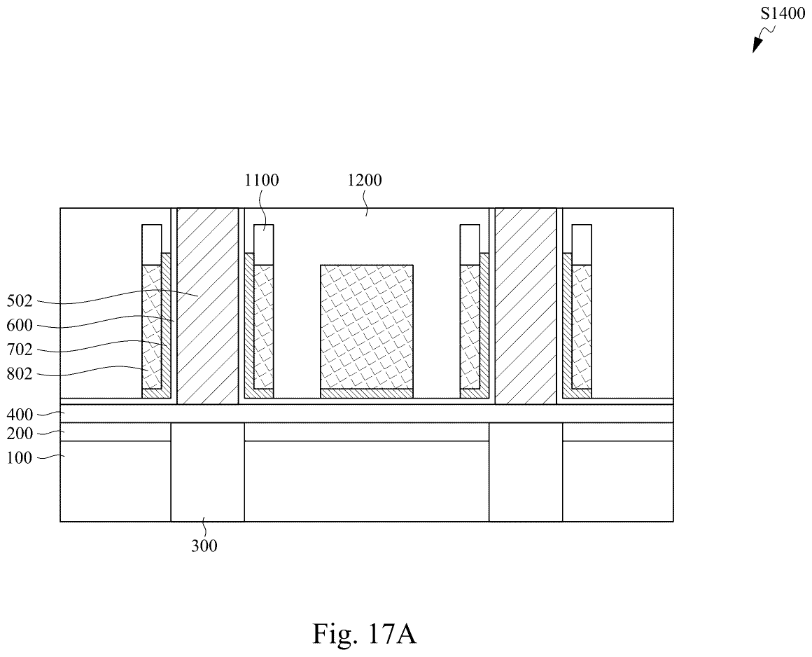

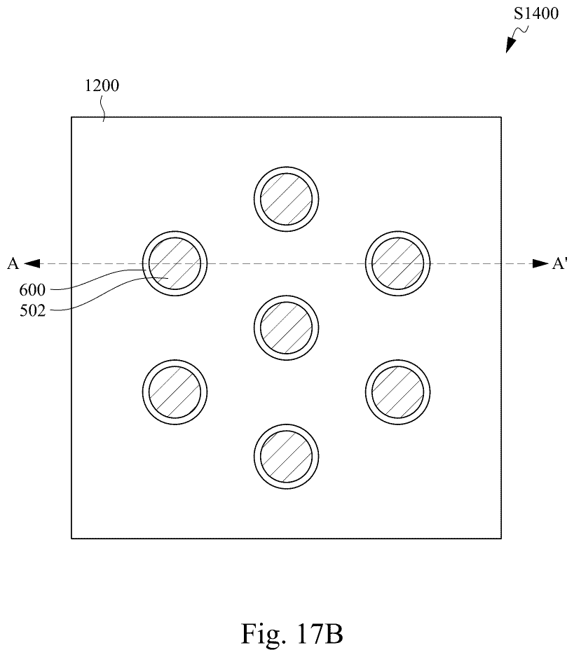

The method M50 proceeds to operation S1400 by refilling a fifth dielectric layer. Referring to FIG. 17A and FIG. 17B, a fifth dielectric layer 1200 is deposited and refilled on top of the liner layer 600, the spacer 1100, the gate electrode 702, the dummy channel structure 502, and the word line 802.

In some embodiments, the fifth dielectric layer 1200 is made with a dielectric material. In some embodiments, the fifth dielectric layer 1200 is made with the same material as the spacer 1100, the liner layer 600, the third dielectric layer 400, or the first dielectric layer 100. In some embodiments, the fifth dielectric layer 1200 is made with silicon dioxide (SiO₂).

In some embodiments, the fifth dielectric layer 1200 may be deposited by using CVD, PECVD, ALD, PVD, LPCVD, FCVD, or other suitable deposition processes. Then, a planarization (e.g. a CMP process) may be performed on the fifth dielectric layer 1200 to remove the excess portions of the fifth dielectric layer 1200 on top of the dummy channel structure 502 so as to level the fifth dielectric layer 1200 with the dummy channel structure 502. In some embodiments, the planarization process may stop when the dummy channel structure 502 is exposed.

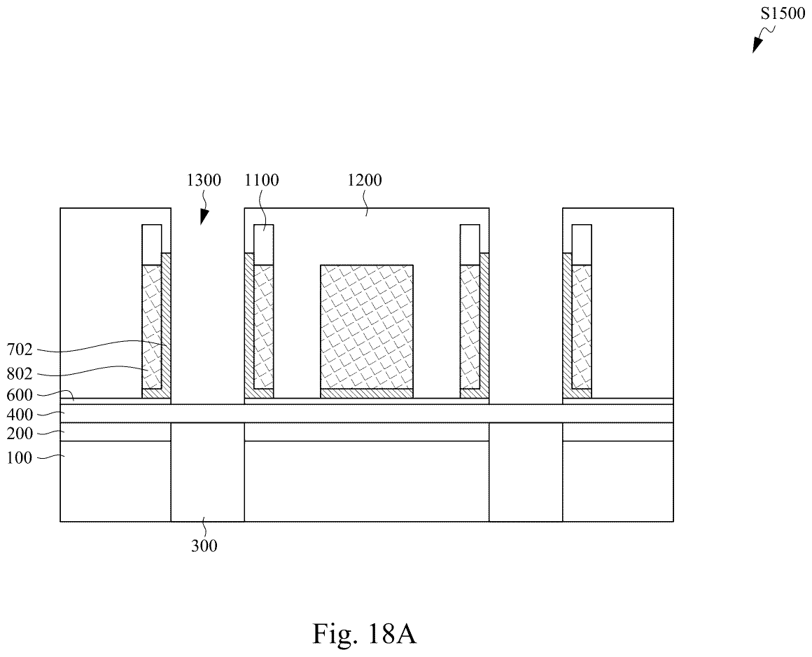

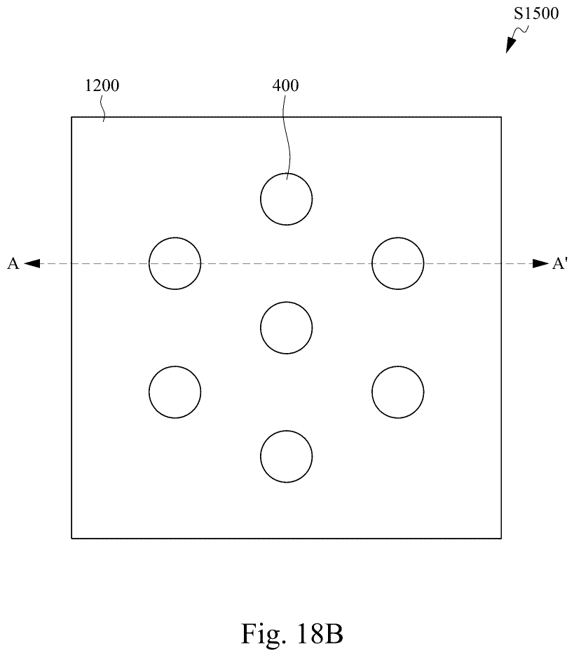

The method M50 proceeds to operation S1500 by removing the dummy channel structure. Referring to FIG. 18A and FIG. 18B, the dummy channel structures 502 are removed and the openings 1300 are formed in the respective gate electrodes 702.

In some embodiments, an etching process is performed to remove the dummy channel structure 502. In some embodiments, the etching process is a wet dip process. In some embodiments, the etching process is configured to remove the material of the dummy channel structure 502. In some embodiments, the etching process may also remove the liner layer 600. In some embodiments, the openings 1300 are formed in replace of the dummy channel structures 502.

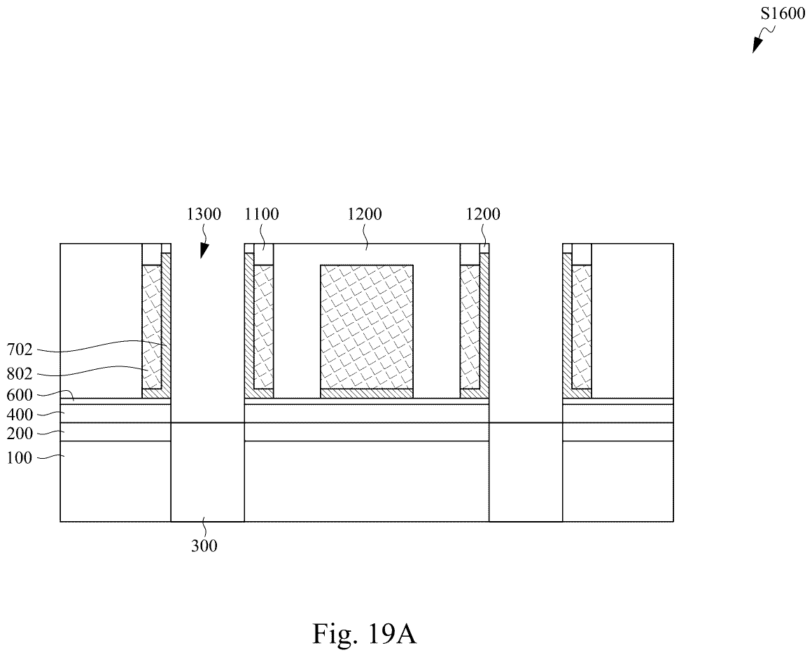

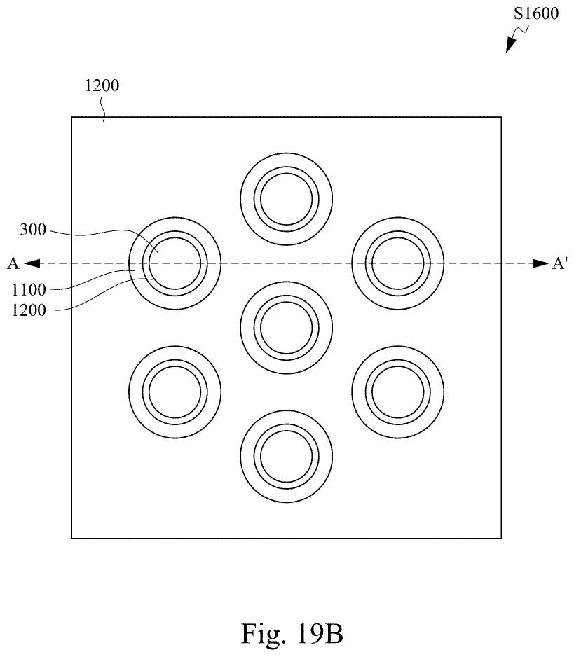

The method M50 proceeds to operation S1600 by removing the third dielectric layer. Referring to FIG. 19A and FIG. 19B, portions of the third dielectric layer 400 on top of the capacitors 300 are removed.

In some embodiments, an etching process is performed to remove the third dielectric layer 400 on top of the capacitors 300. In some embodiments, the top surface of the capacitor 300 is exposed in the opening 1300.

In some embodiments, the fifth dielectric layer 1200 may also be etched during the etching process. In other words, the etching process levels a portion of the fifth dielectric layer 1200. In some embodiments, the etching process removes a portion of the fifth dielectric layer 1200 but leaves a small portion of the fifth dielectric layer 1200 on gate electrode 702 intact. In other words, the etching process does not expose the gate electrodes 702.

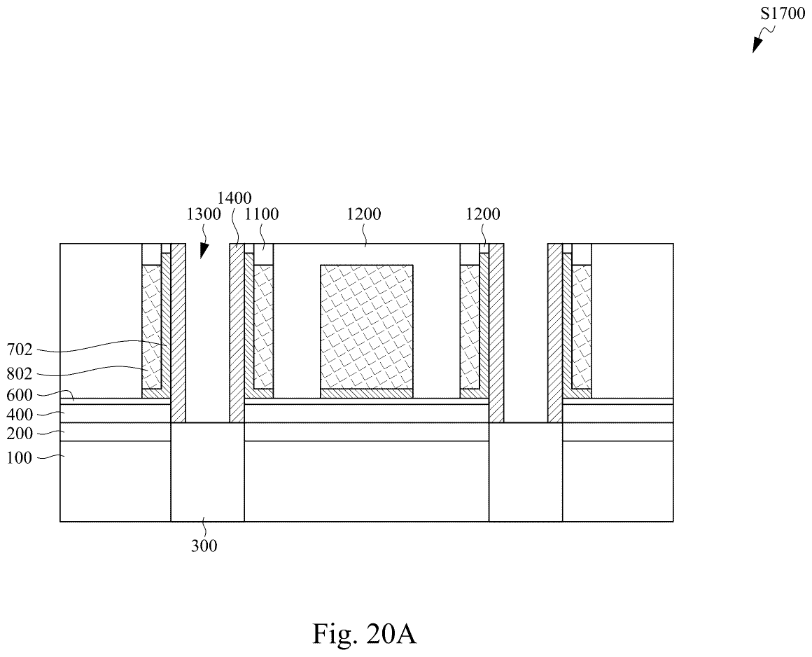

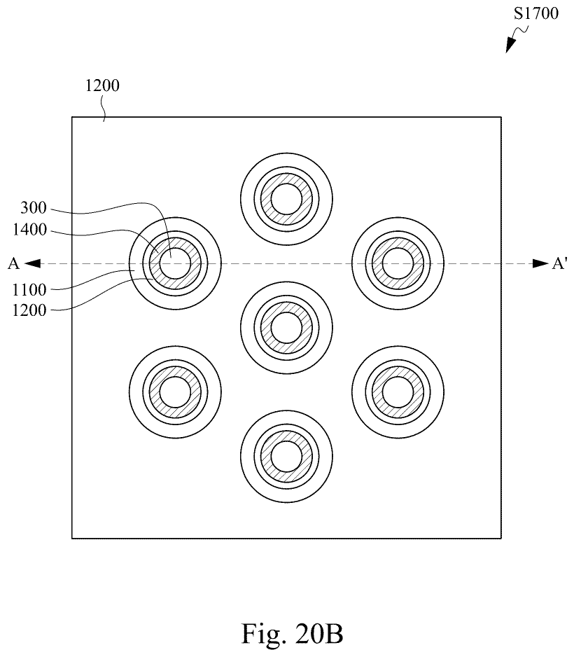

The method M50 proceeds to operation S1700 by forming a gate dielectric on the sidewalls of the opening. Referring to FIG. 20A and FIG. 20B, a gate dielectric 1400 is formed on the sidewalls of the opening 1300. Specifically, a gate dielectric 1400 extending upward from the capacitor 300 and extending along the sidewalls of the opening 1300 is formed.

In some embodiments, the gate dielectric 1400 is made with a dielectric material. In some embodiments, the gate dielectric 1400 may include silicon oxide (SiO), silicon nitride (SiN), silicon oxynitride (SiON), or the like. In some embodiments, the gate dielectric 1400 is configured to electrically separate the gate electrode 702 and a conductive structure (e.g. a channel structure) that will be formed in the subsequent steps.

In some embodiments, a gate dielectric material blanket (not shown) may be formed over the underlying structure (e.g., the fifth dielectric layer 1200 and the capacitor 300). The gate dielectric material blanket may be deposited by using CVD, PECVD, ALD, PVD, LPCVD, FCVD, or other suitable deposition processes. Then, an etching process is performed on the gate dielectric material blanket to remove the horizontal portions of the gate dielectric material blanket, leaving only the vertical portions of the gate dielectric material remaining along sidewalls of the openings 1300. The remaining vertical portions are referred to as the gate dielectric 1400.

In some embodiments, the top end of the gate dielectric 1400 may be substantially leveled with the top surface of the fifth dielectric layer 1200. In some embodiments, the top surface of the gate dielectric 1400 is higher than the top surface of the gate electrode 702.

In some embodiments, the bottom surface of the gate dielectric 1400 is lower than the bottom surface of the gate electrode 702. In some embodiments, the gate dielectric 1400 extends vertically from the top surface of the capacitor 300. In some embodiments, the gate dielectric 1400 has a linear cross-sectional profile. In some embodiments, the fifth dielectric layer 1200 is in contact with a sidewall of the gate dielectric 1400.

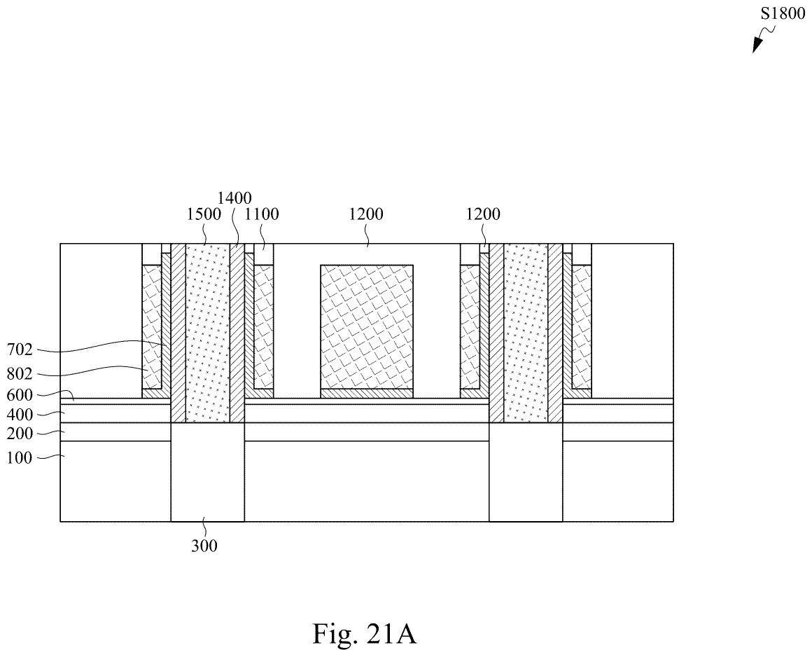

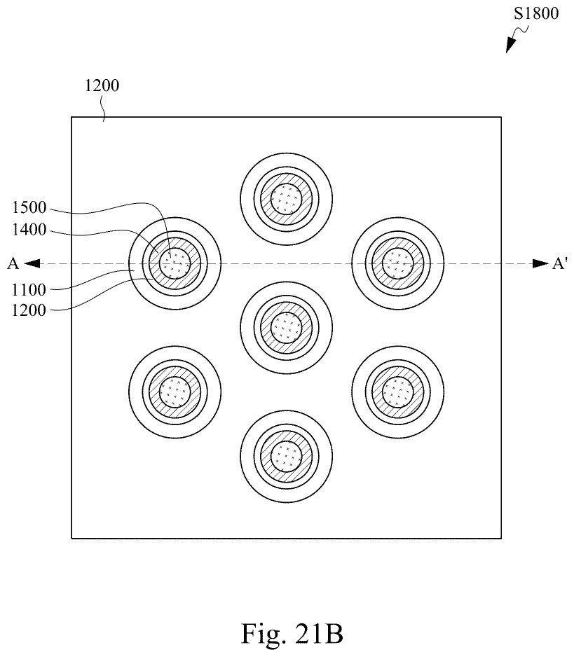

The method M50 proceeds to operation S1800 by forming a channel structure in the opening. Referring to FIG. 21A and FIG. 21B, a channel structure 1500 is formed in the opening 1300. Specifically, the channel structure 1500 is formed on the capacitor 300 and is surrounded by the gate dielectric 1400.

In some embodiments, a channel layer (not shown) may be formed over the underlying structure (e.g., the fifth dielectric layer 1200, the gate dielectric 1400, and the capacitor 300). The channel layer may be deposited by using CVD, PECVD, ALD, PVD, LPCVD, FCVD, or other suitable deposition processes. Then, a planarization (e.g. a CMP process) may be performed on the channel layer to remove the excess portions of the channel layer on top of the fifth dielectric layer 1200 as well as to level the channel layer with the fifth dielectric layer 1200. In some embodiments, the planarization may stop when the fifth dielectric layer 1200 is exposed. The remaining portion of the channel layer is referred to as the channel structure 1500.

In some embodiments, the channel structure 1500 extends vertically from the capacitor 300. In some embodiments, the channel structure 1500 has a vertical length that is substantially the same as the gate dielectric 1400. In some embodiments, the channel structure 1500 may be electrically connected to the underneath capacitor 300. In some embodiments, a bit line structure (not shown) may be above the channel structure 1500.

In some embodiments, the channel structure 1500 may include an oxide semiconductor (OS) material. In some embodiments, the channel structure 1500 may include indium gallium zinc oxide (IGZO). In some embodiments, the channel structure 1500 may include stacked nanowire structure configured such that the current flows out-of-plane (e.g., vertically). The vertical channel structure 1500 may improve the memory cell density in the semiconductor device 50.

In some embodiments, the channel structure 1500 may be wrapped by the gate electrode 702 through the gate dielectric 1400. In other words, the gate electrode 702, the gate dielectric 1400, and the channel structure 1500 may form a gate-all-around (GAA) configuration. Being gate-all-around, the channel structure 1500 has maximized the contact surface and thus the electric current with the gate electrode 702 through the gate dielectric 1400. Therefore, the gate electrode 702 may have a higher speed switching performance and may better control the gate-all-around channel structure 1500 compared to a planar channel structure.

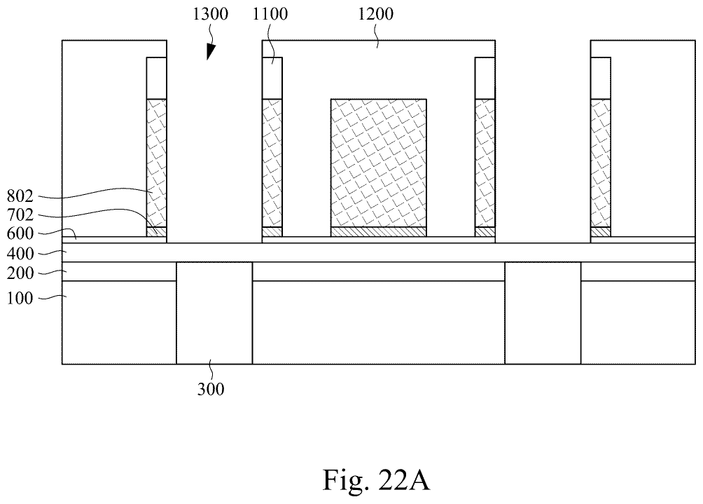

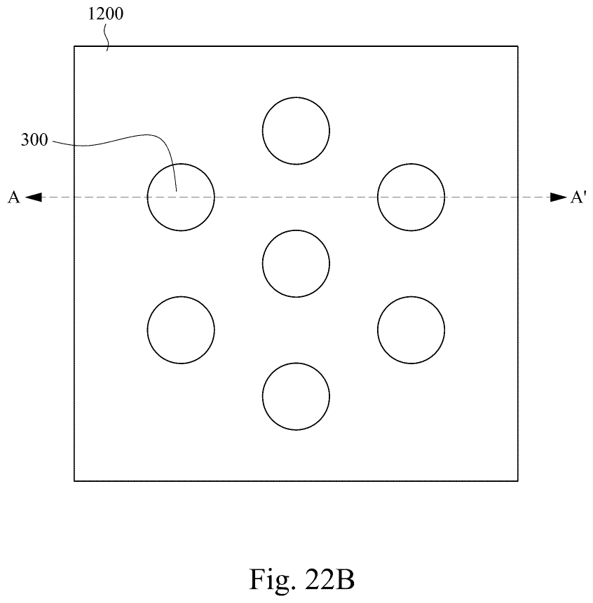

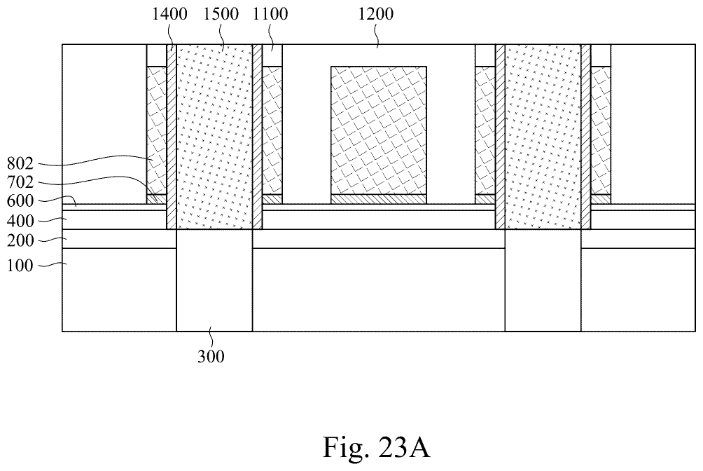

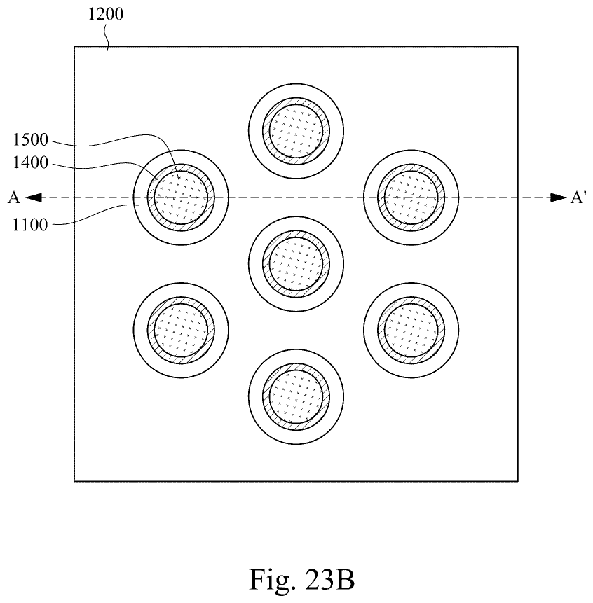

FIGS. 22A to 23B illustrate a method of fabricating a semiconductor device, in accordance with some embodiments of the present disclosure. Reference is made to FIGS. 22A and 22B, FIGS. 22A and 22B are similar to FIGS. 18A and 18B. The embodiment of FIGS. 22A and 22B is different from the embodiment of FIGS. 18A and 18B, in that in some embodiments, the etching process is performed to remove both the dummy channel structure 502 and part of the gate electrode 702 to expose the sidewall of the word line material 802. In some embodiments, the exposed word line 802 is used as a gate electrode to control the channel structure that will be formed in the subsequent process. In some embodiments, the openings 1300 are formed in replace of the dummy channel structures 502 and the removed part of the gate electrode 702.

The structure of FIGS. 22A and 22B may undergo the same processes as discussed in FIGS. 19A to 21B, and the resulting structure is shown in FIGS. 23A and 23B. In the embodiments of FIGS. 23A and 23B, the channel structure 1500 may extend vertically from the capacitor 300. In some embodiments, the gate dielectric 1400 may extend vertically from the second dielectric layer 200. In some embodiments, the gate dielectric 1400 may be in contact with the sidewall of the spacer 1100, the sidewall of the word line 802 and the sidewall of the gate electrode 702. In some embodiments, the top surface of the gate dielectric 1400 may be higher than the top surface of the word line 802. In some embodiments, the gate electrode 702 may extend from the bottom surface of the word line 802. In some embodiments, word line 802 can function as a gate electrode to control the channel structure 1500.

To sum up, the present disclosure provides a method to fabricate a vertical gate-all-around structure, which is beneficial for device shrinkage purpose. On the other hand, the present disclosure provides a method for forming the channel structures by forming dummy channel structures and then replacing the dummy channel structures with the channel structures. Accordingly, channel structures can be formed in a self-aligned manner, and may be formed in a good shape, in which the device performance may be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of fabricating a semiconductor device, comprising:
forming a dummy channel structure;
forming a gate electrode surrounding the dummy channel structure;
forming a word line surrounding the gate electrode;
removing the dummy channel structure to form an opening;
forming a gate dielectric in the opening; and
forming a channel structure in the opening.

2. The method of claim 1, wherein the dummy channel structure is formed overlapping a capacitor.

3. The method of claim 2, further comprising forming a dielectric layer on the capacitor, wherein the dummy channel structure is formed on the dielectric layer.

4. The method of claim 2, wherein the opening exposes the capacitor.

5. The method of claim 2, wherein the gate dielectric is formed extending vertically from the capacitor and along a sidewall of the opening.

6. The method of claim 1, further comprising etching back the gate electrode such that a top surface of the gate electrode is lower than a top surface of the dummy channel structure.

7. The method of claim 1, wherein the word line is formed with a top surface lower than a top surface of the gate electrode.

8. The method of claim 1, wherein forming the word line comprises:
forming a word line material surrounding the dummy channel structure;
forming a hard mask structure over the word line material; and
etching the word line material through the hard mask structure to form the word line.

9. The method of claim 8, wherein the hard mask structure is formed overlapping the dummy channel structure.

10. The method of claim 8, further comprising forming a spacer along a sidewall of the hard mask structure before etching the word line material.

11. A semiconductor device, comprising:
a capacitor;
a channel structure extending vertically from a top surface of the capacitor;
a gate dielectric surrounding the channel structure;
a gate electrode surrounding the gate dielectric; and
a word line surrounding the gate electrode.

12. The semiconductor device of claim 11, wherein the gate dielectric has a linear cross-sectional profile.

13. The semiconductor device of claim 11, wherein the gate dielectric extends vertically from a top surface of the capacitor.

14. The semiconductor device of claim 11, wherein a bottom surface of the gate dielectric is lower than a bottom surface of the gate electrode.

15. The semiconductor device of claim 11, wherein a top surface of the gate dielectric is higher than a top surface of the gate electrode.

16. The semiconductor device of claim 11, further comprising a dielectric layer in contact with a sidewall of the gate dielectric.

17. The semiconductor device of claim 11, wherein the channel structure is made with an oxide semiconductor material.

18. The semiconductor device of claim 17, wherein the channel structure is made with indium gallium zinc oxide (IGZO).

19. The semiconductor device of claim 11, wherein the gate electrode has a ring-shape top profile.

20. The semiconductor device of claim 19, wherein the word line has a bar-shape top profile.
